(19) United States
(12) Patent Application Publication
(10) Pub. No.: US 2007/0173040 A1
(43) Pub. Date: Jul. 26, 2007

(54) Method of reducing an inter-atomic bond strength in a substance

(75) Inventors: Nirmal David Theodore, Mesa, AZ (US); Stephen N. Schauer, Phoenix, AZ (US); Clarence Tracy, Tempe, AZ (US)

Correspondence Address: Kenneth A. Nelson;Bryan Cave LLP, Two North Central Avenue, Suite 2200, Phoenix, AZ, 85004-4406, US

(73) Assignee: Freescale Semiconductor, Inc., Austin, TX (US)

(21) Appl. No.: 11/329,324

(22) Filed: Jan. 9, 2006

(51) Int. Cl. H01L 21/20

(52) U.S. Cl. 438/507; 438/509; 257/E21.134

(57) ABSTRACT

A method of reducing an inter-atomic bond strength in a substance includes the steps of: providing a target material (110, 910, 1210, 1260, 1410, 1460); exposing the target material to a particle flood (140); and annealing the target material while exposing the target material to the particle flood. As an example, the target material can be a collection of non-activated dopant atoms within a semiconducting material. As another example, the target material can be a semiconducting material in an amorphous form. In a different embodiment of the invention an electrically conducting material (950, 1250, 1270, 1450, 1470, 1480) is used as an electron source rather than a particle flood, and an electrically conducting diffusion barrier (940) is placed between the electrically conducting material and the target material.

### FIELD OF THE INVENTION

This invention relates generally to semiconductor components, and relates more particularly to inter-atomic structure, within semiconductor components.

### BACKGROUND OF THE INVENTION

Some semiconductor applications cannot withstand the high temperatures and generous thermal budget that are normal and acceptable with some semiconductor manufacturing processes. For example, applications requiring a lowered thermal budget include polymer based flexible displays and applications in which a heterostructure includes materials with significantly different thermal expansion coefficients. Unless a lowered thermal budget is provided, the foregoing and other devices may suffer from problems such as substrate warpage and unwanted inter-diffusion. A first step toward providing a lowered thermal budget is to deposit an appropriate semiconducting material in amorphous rather than crystallized form because amorphous semiconductors can be formed at lower temperatures. Amorphous semiconducting material, however, does not perform as well as crystalline semiconducting material. Carrier mobility, for example, is far lower in amorphous semiconductors than it is in crystalline semiconductors. Accordingly, there is a need for a method of crystallizing an amorphous semiconducting material at relatively low temperature such that the benefits of crystalline semiconducting material may be realized without a thermal budget penalty. There also exists a need for a method of dopant activation at lower temperature.

### BRIEF DESCRIPTION OF THE DRAWINGS

The invention will be better understood from a reading of the following detailed description, taken in conjunction with the accompanying figures in the drawings in which:

FIG. 1 is a cross sectional view of a substance at a particular stage in an inter-atomic bond strength reduction process according to an embodiment of the invention;

FIG. 2 is a cross sectional view of the substance of FIG. 1 at a later stage in the inter-atomic bond strength reduction process, according to an embodiment of the invention;

FIG. 3 is a flowchart illustrating a method of reducing an inter-atomic bond strength in a substance according to an embodiment of the invention;

FIG. 4 is a cross sectional view of the substance of FIG. 1 at a particular stage in an inter-atomic bond strength reduction process according to a different embodiment of the invention;

FIG. 5 is a cross sectional view of the substance of FIG. 1 at a later stage in the inter-atomic bond strength reduction process according to the different embodiment of the invention;

FIG. 6 is a three-quarters cross sectional view of the substance of FIG. 1 at a later stage in the inter-atomic bond strength reduction process according to the different embodiment of the invention;

FIG. 7 is a three-quarters cross sectional view of the substance of FIG. 1 at a still later stage in the inter-atomic bond strength reduction process according to the different embodiment of the invention;

FIG. 8 is a flowchart illustrating a method of reducing an inter-atomic bond strength in a substance according to an embodiment of the invention;

FIG. 9 is a cross sectional view of a different substance at a particular stage in an inter-atomic bond strength reduction process according to an embodiment of the invention;

FIG. 10 is a cross sectional view of the substance of FIG. 9 at a later stage in the inter-atomic bond strength reduction process according to an embodiment of the invention;

FIG. 11 is a flowchart illustrating a method of reducing an inter-atomic bond strength of a semiconducting material according to an embodiment of the invention;

FIG. 12 is a cross sectional view of a different substance at a particular stage in an inter-atomic bond strength reduction process according to an embodiment of the invention;

FIG. 13 is a flowchart illustrating a method of reducing an inter-atomic bond strength of a semiconducting material according to a different embodiment of the invention;

FIG. 14 is a cross sectional view of a different substance at a particular stage in an inter-atomic bond strength reduction process according to an embodiment of the invention; and

FIG. 15 is a flowchart illustrating a different method of reducing an inter-atomic bond strength of a semiconducting material according to an embodiment of the invention.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner.

### DETAILED DESCRIPTION OF THE DRAWINGS

The lowering of crystallization temperature and of dopant activation temperature appears to be due to a bond screening mechanism in which mobile electrons contributed from an electron source diffuse into a target material, such as an amorphous semiconducting material or a semiconducting material containing non-activated dopant atoms, and provide local screening of the inter-atomic bonds. Such screening reduces the stability and strength of the inter-atomic bonds, thus providing the atoms with an increased ability to rearrange themselves. Accordingly, the discussion herein will often refer to a reduction in an inter-atomic bond strength. As an example, the activation energy required to break the amorphous Si—Si bond in the presence of an aluminum based bond screening has been measured by the inventors to be approximately 0.6 electron-volts (eV), while the activation energy required to break Si—Si bonds in polysilicon without bond screening has been measured to be approximately 2.2-2.4 eV.

In one embodiment of the invention, a method of reducing an inter-atomic bond strength in a substance comprises the steps of: providing a target material; exposing the target material to an electron flood at an exposure temperature; and annealing the target material at an anneal temperature while exposing the target material to the electron flood. As an example, the exposure temperature in one embodiment is greater than approximately 22 degrees Celsius (C.), which is to say greater than approximately room temperature. In a particular embodiment, the exposure temperature is greater than approximately 45 degrees C. In the same or another embodiment, the exposure temperature is approximately equal to the anneal temperature.

As known in the art, exposing the target material to an electron flood is to flood the surface of the target material with electrons, either in the form of a broad beam or a rastered narrow beam.

In a different embodiment the target material is exposed (at an exposure temperature) to a flood of particles other than electrons. As an example, the particle flood could be a flood of ions, photons, or neutral particles, i.e., particles having no net electrical charge, including neutrons, neutral atoms, neutral molecules, and the like. The phrase “particle flood” will be used herein to mean a flood of any of the particles mentioned in this paragraph, plus similar particles. Atoms suitable for a particle flood in accordance with embodiments of the invention include silicon, gallium, arsenic, indium, antimony, nitrogen, and the like, including any atomic material used in molecular beam epitaxy (MBE). Molecules suitable for a particle flood in accordance with embodiments of the invention include hydrogen (H₂), deuterium (D₂), boron difluoride (BF₂), oxygen (O₂), nitrogen (N₂), and the like. In an embodiment where the particle flood comprises an ion flood, it should be noted that the ions making up the ion flood may be of a different species than the particles that make up the target material.

As an example, the target material can be a collection of non-activated dopant atoms within a semiconducting material. As another example, the target material can be a semiconducting material in an amorphous form. In a different embodiment of the invention an electrically conducting material, rather than an electron flood, is used as a source of electrons or ions, and a diffusion barrier is placed between the electrically conducting material and the target material. The anneal process in conjunction with the electron source alters a physical property of the target material. The phrase “alter a physical property of,” as used herein, includes at least one of: (1) the crystallization or partial crystallization of an amorphous semiconducting material; and (2) the activation of a collection of dopant atoms.

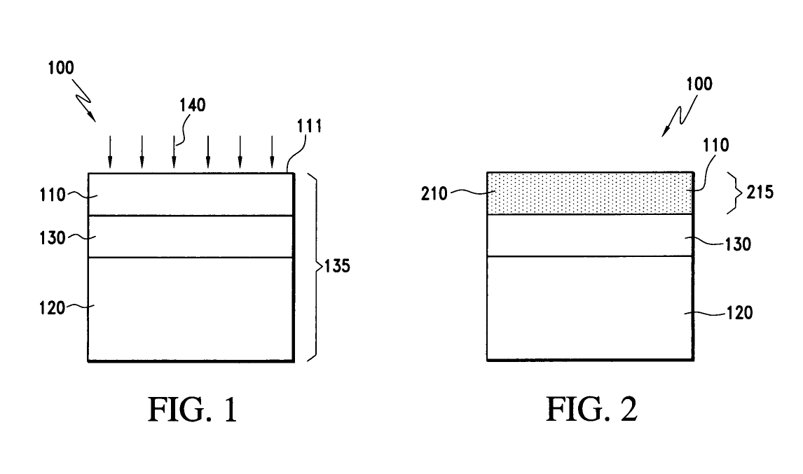

FIG. 1 is a cross sectional view of a substance 100 at a particular stage in an inter-atomic bond strength reduction process, according to an embodiment of the invention. As illustrated in FIG. 1, substance 100 comprises a target material 110 having a surface 111. Target material 110 may form a portion of a larger substance, as in the illustration, or it may encompass the entire substance.

In the illustrated embodiment, target material 110 comprises a layer of semiconducting material in an amorphous form that has been formed over a substrate 120 and an insulating material 130. Substrate 120, insulating material 130, and target material 110 comprise a wafer 135. As an example, substance 100 may be a substance in a semiconductor-on-insulator (SOI) embodiment in which target material 110 may comprise a layer of amorphous silicon, substrate 120 may comprise a silicon substrate, and insulating material 130 may comprise an oxide. Substrate 120 may be an amorphous substrate. Other semiconducting materials, such as germanium and silicon germanium, may also be used for substrate 120 and target material 110. Additionally, target material 110 may comprise an electrically insulating material or an electrically conducting material in any situation where it is beneficial to reduce an inter-atomic bond strength, to cause a rearrangement of such bonds, or to cause a phase change in the material. However, for purposes of the following discussion, silicon and oxide will generally be used as example materials. Similarly, the phrase “semiconducting material 110” will be used interchangeably with the phrase “target material 110,” where such a substitution fits the context of the discussion, although it should be understood that target material 110 also includes materials other than semiconducting materials, as mentioned above. As an example, various places in the following discussion will make reference only to the crystallization of a semiconducting material, but it should be understood that, where the context permits, such discussion should be taken to include dopant activation as well.

In a different (non-illustrated) embodiment, insulating material 130 may be omitted from substance 100, and target material 110 may be provided directly on top of substrate 120. In that non-illustrated embodiment, wafer 135 comprises substrate 120 and target material 110, but does not comprise insulating material 130. In still a different embodiment, target material 110 comprises a collection of non-activated dopant atoms within a semiconducting material. In any event, annealing the wafer does not begin until after the wafer includes the target material.

Target material 110 is being exposed in FIG. I to an electron flood 140 that is a blanket electron flood. Electron flood 140 may be produced by an electron flood gun (not shown) in a manner known in the art.

FIG. 2 is a cross sectional view of substance 100 at a later stage in the inter-atomic bond strength reduction process following a low-temperature anneal, according to an embodiment of the invention. The anneal procedure can be conducted according to methods known in the art. As a result of the decrease in inter-atomic bond strength caused by electron flood 140, the anneal can take place at an anneal temperature below approximately 600 degrees C., which is a standard anneal temperature for solid phase crystallization of amorphous silicon, and more particularly can take place at an anneal temperature no greater than approximately 300 degrees C. The relatively low anneal temperatures just described help meet lowered thermal budget requirements of various applications as mentioned above, and also provide a means of achieving sharp dopant profile transitions that are not possible at higher anneal temperatures.

Shading 210 within target material 110 in FIG. 2 indicates that a change in atomic structure has taken place between the stages of the inter-atomic bond strength reduction process that are depicted in FIGS. 1 and 2. In an embodiment where target material 110 is originally amorphous silicon, shading 210 indicates a transformation into, depending on anneal conditions, polycrystalline or nano-crystalline silicon. In an embodiment where target material 110 comprises a collection of non-activated dopant atoms within a semiconducting material, shading 210 indicates that the non-activated dopant atoms have been activated. Such change in the atomic structure occurs at and under a portion of a surface of the semiconducting material that is exposed to electron flood 140 while wafer 135 is at the anneal temperature. FIG. 1, as mentioned, depicts a blanket electron flood that covers substantially all of the surface of semiconducting material 110 and results in the blanket layer of nano-crystalline silicon or polysilicon shown in FIG. 2.

A thickness 215 of target material 110 is such that the inter-atomic bond strength reduction process enables the low-temperature crystallization or activation of all of target material 110. Target materials of greater thickness may not be entirely crystallized or activated, and may require a slightly modified procedure as discussed below.

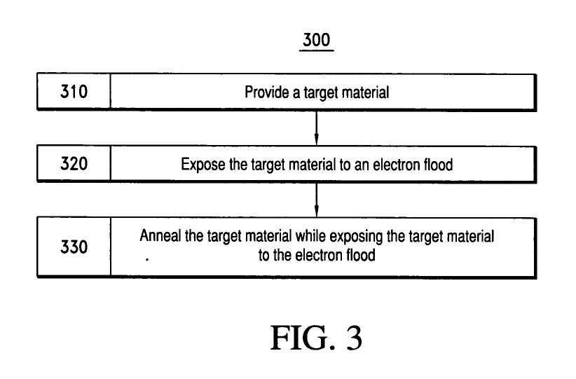

FIG. 3 is a flowchart illustrating a method 300 of reducing an inter-atomic bond strength in a substance according to an embodiment of the invention and as shown in FIGS. 1 and 2. A step 310 of method 300 is to provide a target material, which for example can be similar to target material 110, first shown in FIG. 1. In one embodiment, step 310 or another step can comprise providing a substrate before providing the target material, and providing the target material can comprise forming the target material over the substrate.

A step 320 of method 300 is to expose the target material to an electron flood, which for example can be similar to electron flood 140, first shown in FIG. 1. A step 330 of method 300 is to anneal the target material while exposing the target material to the electron flood. In one embodiment, method 300 further comprises introducing the target material into a semiconducting substrate before performing steps 320 and 330. In a different embodiment, the target material could be the substrate itself.

FIG. 4 is a cross sectional view of substance 100 at a particular stage in an inter-atomic bond strength reduction process, according to a different embodiment of the invention. As illustrated in FIG. 4, a hard mask 410 has been deposited and patterned, using standard techniques, above wafer 135 before the wafer is annealed. Hard mask 410 defines regions 420 of target material 110 that is exposed to electron flood 140 and thus is crystallized during the anneal. As an example, hard mask 410 can comprise an oxide, a nitride, or the like. As a particular example, hard mask 410 can comprise silicon dioxide.

As an example, hard mask 410 can comprise a dielectric material, an electrically conducting material, or a stack comprising a dielectric material and an electrically conducting material. A mask made of electrically conducting material reduces charging effects, and associated distortion, that can occur with a mask made of dielectric material.

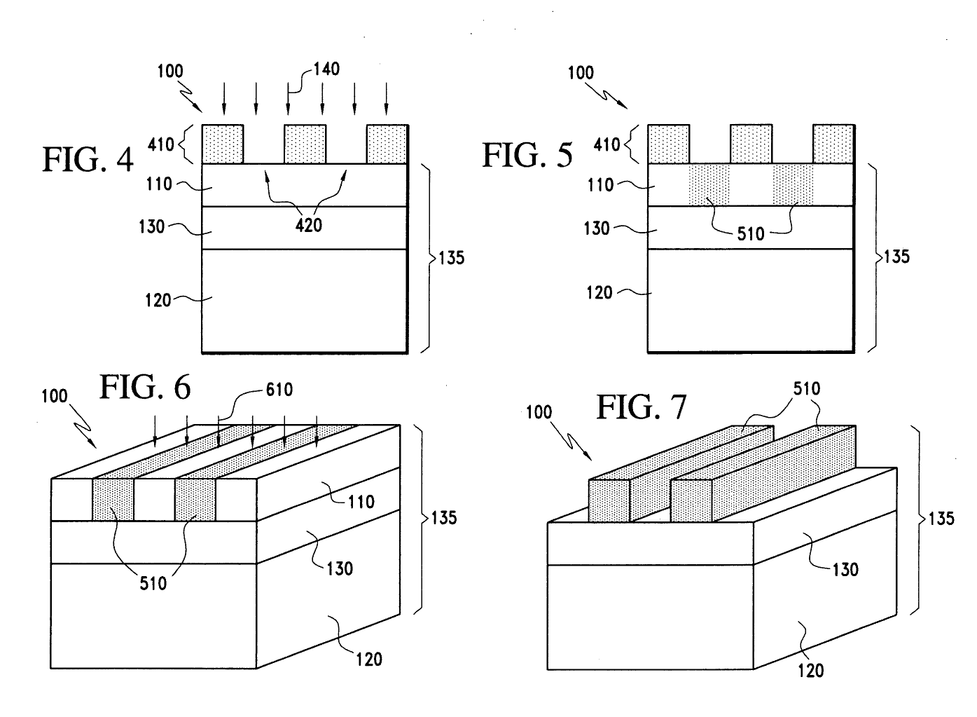

FIG. 5 is a cross sectional view of substance 100 at a later stage in the inter-atomic bond strength reduction process according to the different embodiment of the invention. The stage depicted in FIG. 5 is a stage that occurs subsequent to the electron flood and the low temperature anneal. FIG. 5 illustrates regions 510 of crystallized semiconducting material, resulting from the electron flood and the anneal, which regions 510 correspond to exposed regions 420 (see FIG. 4).

FIG. 6 is a three-quarters cross sectional view of substance 100 at a later stage in the inter-atomic bond strength reduction process according to the different embodiment of the invention. FIG. 7 is a three-quarters cross sectional view of substance 100 at a still later stage in the inter-atomic bond strength reduction process according to the different embodiment of the invention. The stage depicted in FIG. 6 is a stage that occurs subsequent to the removal of hard mask 410 (FIG. 4). FIG. 6 illustrates the performance of a selective etch, represented by arrows 610 and performed according to a method known in the art, that selectively removes amorphous silicon. The result, shown in FIG. 7, is a pattern of nano-crystalline silicon or polysilicon. Such patterns may be optimized for a particular application for which substance 100 is intended. As an example, certain memory applications benefit from the presence of a band of higher-conductivity nano-crystalline silicon surrounded by a lower-conductivity matrix of amorphous silicon.

In one embodiment, the method further comprises applying an electrical bias to wafer 135 in order to define the location where crystallization occurs. The applied electric field enhances diffusion of charged point defects that can contribute to the crystallization process or the dopant activation process.

The electrical bias can be global or can be applied only to a portion of wafer 135. As an example, in one embodiment the electrical bias can be applied only to surface 111 of semiconducting material 110. In that embodiment, the local electrical biasing may be applied using either on-wafer electrodes or off-wafer electrodes, as known in the art. In another embodiment, wafer 135 may be placed in an electric field gradient in which the electrically conducting layer is at a different electric field value than substrate 120, resulting in an apparent electrical bias between the two. In yet another embodiment, an electrical bias may be applied between a physical electrical contact on a back of wafer 135 and a probe contact on a pad (not shown) on a top of wafer 135, where the pad connects to the electrically conducting layer.

In the same or another embodiment, the method further comprises providing a seed window (not shown) adjacent to semiconducting material 110 where semiconducting material 110 physically contacts substrate 120. The seed window is capable of serving as an initiation site for crystallization. A seed window has application, for example, in the context of an epitaxial lateral overgrowth process wherein a crystalline substrate is exposed within a small opening-the seed window—where it acts as a seed for crystalline growth.

An alternative process, not fully illustrated herein but described with reference to FIGS. 5-7, may also achieve the FIG. 7 result. In the alternative process, substance 100 is brought to the stage depicted in FIG. 5, after which hard mask 410 is removed from wafer 135. An inverse mask, so called because it is the inverse of hard mask 410, is then formed over target material 110 so as to be over regions 510. Unmasked regions of target material 110 are then etched away and the inverse mask is removed. The result, as mentioned, is a pattern of nano-crystalline silicon or polysilicon similar to what is shown in FIG. 7. As is the case with the procedure of FIG. 4-7, the mask deposition and removal and the etching process in the alternative process described above are performed according to techniques known in the art.

In one embodiment of the invention, electron flood 140 does not comprise a blanket electron flood as shown in FIG. 1 but rather comprises a localized electron beam that exposes less than all of surface 111 of semiconducting material 110 to the electrons. The localized electron beam is used to write a pattern on surface 111, or in other words is rastered across surface 111 to create an exposed pattern. The localized electron beam may be thought of as being represented by a subset of the group of arrows that represent electron flood 140 in FIG. 1.

The localized electron beam has an acceleration voltage V_{A}. The acceleration voltage can be adjusted or tuned in order to control the depth to which electrons penetrate semiconducting material 110. Such adjustment may enable control over or optimization of the depth in semiconducting material 110 to which crystallization takes place. As an example, the acceleration voltage may be varied between approximately 10 volts and 200 kilovolts.

The combination of exposure to the localized electron beam and a low temperature anneal results in a pattern of nano-crystalline silicon or polysilicon surrounded by amorphous silicon similar to what is shown in FIG. 6. The pattern of nano-crystalline silicon or polysilicon corresponds to the pattern that was written with the localized electron beam, meaning that crystallization takes place only at the portion of surface 111 that is exposed to the localized electron beam and the semiconducting material underneath the exposed portion. A selective etch that attacks only amorphous silicon may then be used, following the discussion accompanying FIG. 6, with the result being similar to what is depicted in FIG. 7.

Summarizing the method for reducing an inter-atomic bond strength in a substance that is depicted in FIGS. 4-7, hard mask 410 is patterned and etched, then the electron flood/anneal is performed, such that only the areas opened in hardmask 410 receive the electrons and are crystallized. Next, hardmask 410 is removed. A possible extension of the method is to then selectively etch the un-crystallized areas. Another embodiment would be to pattern and etch the amorphous material first, but using a hardmask to do so is unnecessarily complicated. In most cases, one could simply resist mask and etch the amorphous material directly, followed by the electron flood/anneal. This saves the hardmask process steps, which are only required to withstand the anneal temperature conditions.

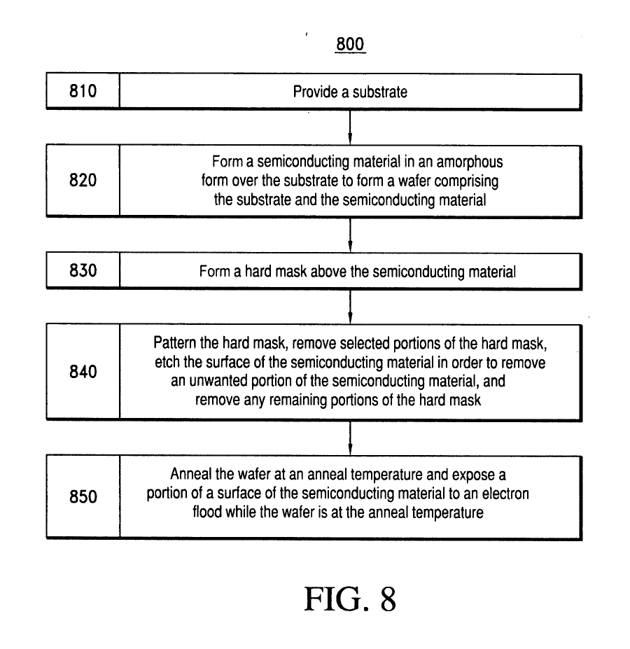

FIG. 8 is a flowchart illustrating a method 800 of reducing an inter-atomic bond strength in a substance according to an embodiment of the invention. A step 810 of method 800 is to provide a substrate, which for example can be similar to substrate 120, first shown in FIG. 1.

A step 820 of method 800 is to deposit a semiconducting material in an amorphous form over the substrate to form a wafer comprising the substrate and the semiconducting material. As an example, the semiconducting material can be similar to target material 110 and the wafer can be similar to wafer 135, both of which were first shown in FIG. 1.

A step 830 of method 800 is to deposit a hard mask above the semiconducting material, which hard mask, for example, can be similar to hard mask 410, first shown in FIG. 4. A step 840 of method 800 is to pattern the hard mask, remove selected portions of the hard mask, etch the surface of the semiconducting material in order to remove an unwanted portion of the semiconducting material, and remove any remaining portions of the hard mask that were not removed during the removal of the selected portions of the hard mask. In one embodiment, patterning the hard mask, removing selected portions of the hard mask, etching the surface of the semiconducting material, and removing any remaining portions of the hard mask can each be performed in separate steps.

A step 850 of method 800 is to anneal the wafer at an anneal temperature in order to at least partially crystallize the semiconducting material, and to expose a portion of a surface of the semiconducting material to an electron flood while the wafer is at the anneal temperature. As an example, the electron flood can be similar to electron flood 140, first depicted in FIG. 1.

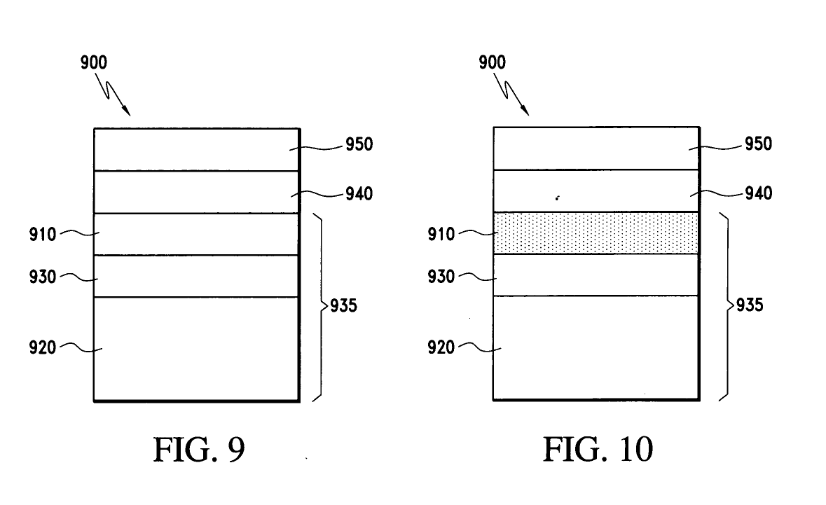

FIG. 9 is a cross sectional view of a substance 900 at a particular stage in an inter-atomic bond strength reduction process according to an embodiment of the invention. FIG. 10 is a cross sectional view of substance 900 at a later stage in the inter-atomic bond strength reduction process according to an embodiment of the invention. The comments made above regarding dopant activation versus semiconducting material crystallization apply as well to the following discussion, and to the entire disclosure herein.

As illustrated in FIG. 9, substance 900 comprises a target material 910 that has been deposited in amorphous form over a substrate 920 and an electrically insulating layer 930. In a non-illustrated embodiment, electrically insulating layer 930 may be omitted from substance 900, and target material 910 may be provided directly on top of substrate 920. In that non-illustrated embodiment, wafer 935 comprises substrate 920 and target material 910, but does not comprise insulating material 930. Target material 910, substrate 920, and electrically insulating material 930 form a wafer 935. As an example, target material 910, substrate 920, electrically insulating material 930, and wafer 935 can be similar to, respectively, target material 110, substrate 120, electrically insulating material 130, and wafer 135 described above and first shown in FIG. 1. Substance 900 further comprises a diffusion barrier 940 over target material 910, and a layer of electrically conducting material 950 over diffusion barrier 940.

The process illustrated in part by FIG. 9 does not include or require an electron flood because electrically conducting material 950, rather than the electron flood, acts as an electron source for the electrons that perform the bond screening. Following a low temperature anneal similar to that first described above in connection with the process depicted in FIGS. 1-2, substance 900 takes the form shown in FIG. 10, in which target material 910 has been crystallized or activated. If desired, an electrical bias may be applied to electrically conducting material 950 in order to achieve the advantages, discussed above, attendant to an electrical bias. Such an electrical bias may be applied in the same manner discussed above.

After the crystallization process has taken place, diffusion barrier 940 and electrically conducting material 950 are removed, at least in selected areas. If diffusion barrier 940 and electrically conducting material 950 were not removed, very few useful devices could be created, as one would then simply be working with a substrate with a blanket film of metal overlying the now improved semiconductor. Complete removal of diffusion barrier 940 and electrically conducting material 950 brings wafer 935 to the point achieved by the electron flood process as shown in FIG. 2.

As an example, electrically conducting material 950 can comprise a metal with low diffusivity in semiconducting material 910. Where semiconducting material 910 comprises silicon, aluminum is an appropriate choice for electrically conducting material 950. In the same or other embodiments, appropriate and useful materials include silver, gold, nickel, tungsten, copper, iron, platinum, palladium, cobalt, titanium nitride, and the like. Aluminum, as is well known, has a high solid-solubility for silicon, and so causes pore formation in the amorphous silicon. For some applications, including light-emissive and sensitive applications, such pore formation may be desirable. Where such pore formation is not desirable, a conducting material having a low solid-solubility for the target material may be selected.

As another example, diffusion barrier 940 may comprise an electrically conducting material such as titanium nitride, tantalum nitride, tantalum silicon nitride, titanium tungsten nitride, or the like. An electrically conducting diffusion barrier facilitates the migration of mobile electrons from electrically conducting material 950 into semiconducting material 910 and contribute to the reduction in the bond strength between atoms therein. Diffusion barrier 940 also eliminates diffusion into electrically conducting material 950 of particles from semiconducting material 910 which would otherwise contribute to pore formation in semiconducting material 910.

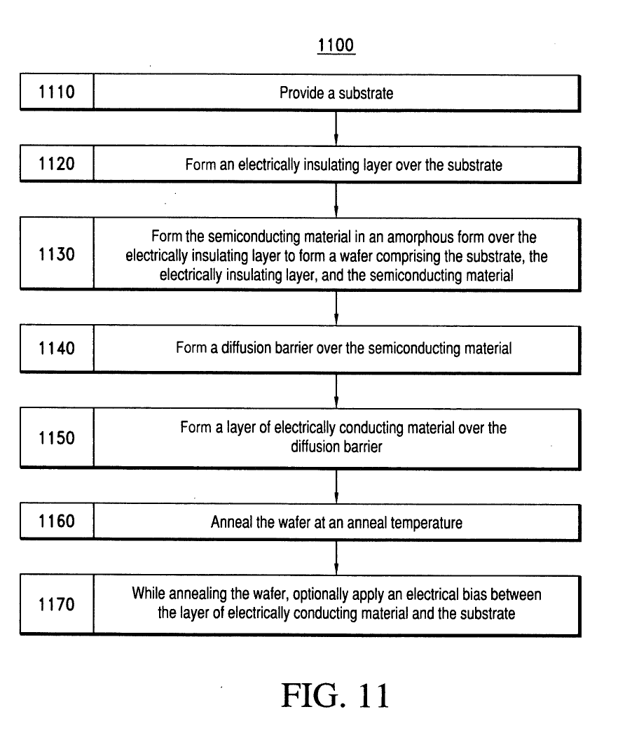

FIG. 11 is a flowchart illustrating a method 1100 of reducing an inter-atomic bond strength of a semiconducting material according to an embodiment of the invention and as shown in FIGS. 9-10. A step 1110 of method 1100 is to provide a substrate, which for example, can be similar to substrate 920, first shown in FIG. 9.

A step 1120 of method 1100 is to deposit an electrically insulating layer over the substrate, and a step 1130 of method 1100 is to deposit the semiconducting material in an amorphous form over the electrically insulating layer to form a wafer comprising the substrate, the electrically insulating layer, and the semiconducting material. As an example, the electrically insulating layer, the semiconducting material, and the wafer can be similar to, respectively, electrically insulating layer 930, semiconducting material 910, and wafer 935, all of which were first shown in FIG. 9.

A step 1140 of method 1100 is to deposit a diffusion barrier over the semiconducting material. A step 1150 of method 1100 is to deposit a layer of electrically conducting material over the diffusion barrier. As an example, the diffusion barrier can be similar to diffusion barrier 940, and the electrically conducting material can be similar to electrically conducting material 950, both of which were first shown in FIG. 9.

A step 1160 of method 1100 is to anneal the wafer at an anneal temperature in order to crystallize the semiconducting material. As an example, the anneal temperature can be less than approximately 600 degrees C., and in particular can be approximately 300 degrees C. or less.

An optional step 1170 is to apply an electrical bias between the layer of electrically conducting material and the substrate. Optional step 1170 is performed, if performed at all, during the wafer anneal of step 1160. In one embodiment, step 1170 is a sub-step or a component of step 1160.

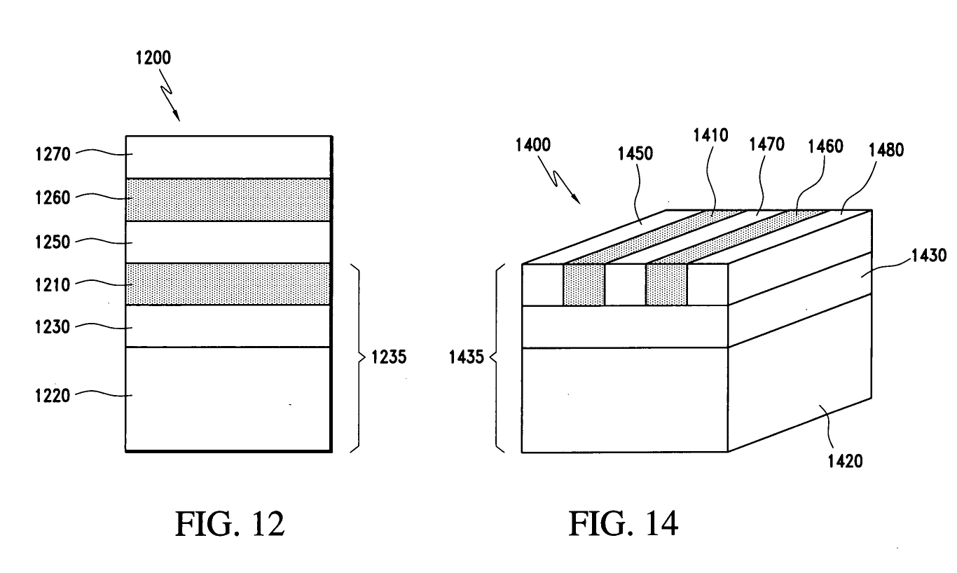

FIG. 12 is a cross sectional view of a substance 1200 at a particular stage in an inter-atomic bond strength reduction process according to an embodiment of the invention. The comments made above regarding dopant activation versus semiconducting material crystallization apply as well to the following discussion, and to the entire disclosure herein.

As illustrated in FIG. 12, substance 1200 comprises a target material 1210 that has been deposited in amorphous form over a substrate 1220 and an electrically insulating layer 1230. In a non-illustrated embodiment, insulating material 1230 may be omitted from substance 1200, and target material 1210 may be provided directly on top of substrate 1220. In that non-illustrated embodiment, wafer 1235 comprises substrate 1220 and target material 1210, but does not comprise insulating material 1230. Target material 1210, substrate 1220, and electrically insulating material 1230 form a wafer 1235. As an example, target material 1210, substrate 1220, electrically insulating material 1230, and wafer 1235 can be similar to, respectively, target material 110, substrate 120, electrically insulating material 130, and wafer 135 described above and first shown in FIG. 1.

Substance 1200 further comprises a layer of electrically conducting material 1250 over target material 1210, a target material 1260, deposited in amorphous form, over electrically conducting material 1250, and a layer of electrically conducting material 1270 over target material 1260. As an example, electrically conducting materials 1250 and 1270 can be similar to electrically conducting material 950, first shown in FIG. 9. As another example, target material 1260 can be similar to target material 1210. The vertical multilayer stack illustrated in FIG. 12 may be useful where the combined thickness of target material 1210 and target material 1260 is so great that crystallization or activation could not occur throughout the entire thickness of the target material if it were a single layer structure.

The process illustrated in part by FIG. 12 does not include or require an electron flood because electrically conducting materials 1250 and 1270, rather than the electron flood, act as an electron source for the electrons that perform the bond screening. FIG. 12 illustrates substance 1200 at a stage in the inter-atomic bond strength reduction process subsequent to a low temperature anneal similar to that first described above in connection with the process depicted in FIGS. 1-2. More specifically, target material 1210 and target material 1260 have been crystallized or activated. If desired, an electrical bias may be applied to electrically conducting material 1250 and/or electrically conducting material 1270 in order to achieve the advantages, discussed above, attendant to an electrical bias. As an example, such an electrical bias may be applied between a probe pad or pads (not shown) that are electrically connected to electrically conducting materials 1250 and 1270 and substrate 1220, or some subset thereof.

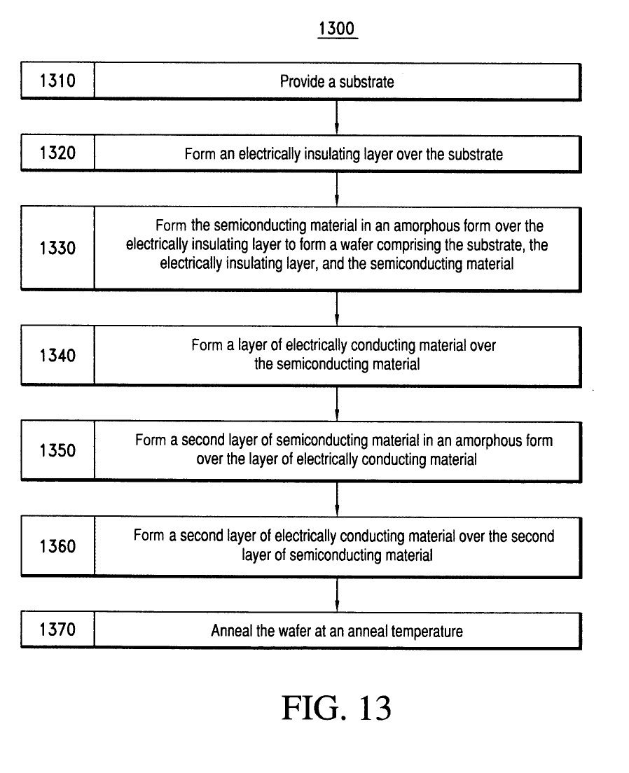

FIG. 13 is a flowchart illustrating a method 1300 of reducing an inter-atomic bond strength of a semiconducting material according to an embodiment of the invention and as shown in FIG. 12. A step 1310 of method 1300 is to provide a substrate, which for example, can be similar to substrate 1220, shown in FIG. 12.

A step 1320 of method 1300 is to deposit an electrically insulating layer over the substrate, and a step 1330 of method 1300 is to deposit the semiconducting material in an amorphous form over the electrically insulating layer to form a wafer comprising the substrate, the electrically insulating layer, and the semiconducting material. As an example, the electrically insulating layer, the semiconducting material, and the wafer can be similar to, respectively, electrically insulating layer 1230, semiconducting material 1210, and wafer 1235, all of which were shown in FIG. 12.

A step 1340 of method 1300 is to deposit a layer of electrically conducting material over the semiconducting material. A step 1350 of method 1300 is to deposit a second layer of semiconducting material in an amorphous form over the layer of electrically conducting material, and a step 1360 of method 1300 is to deposit a second layer of electrically conducting material over the second layer of semiconducting material. As an example, the electrically conducting material, both in the initial layer and the second layer, can be similar to electrically conducting material 1250, shown in FIG. 12. As another example, the second layer of semiconducting material can be similar to semiconducting material 1210, also shown in FIG. 12. As will be readily apparent to one of ordinary skill in the art, the number of layers of electrically conducting material and of amorphous semiconducting material is not limited to two. Indeed, in one embodiment, one or more of steps 1330, 1340, 1350, and 1360, or another step or steps, can comprise forming one or more additional layers of electrically conducting material alternating with one or more additional layers of semiconducting material in amorphous form such that the resulting stack is made up of three or more electrically conducting material—amorphous semiconducting material pairs.

A step 1370 of method 1300 is to anneal the wafer at an anneal temperature in order to crystallize the semiconducting material. As an example, the anneal temperature can be less than approximately 600 degrees C., and in particular can be approximately 300 degrees C. or less.

FIG. 14 is a cross sectional view of a substance 1400 at a particular stage in an inter-atomic bond strength reduction process according to an embodiment of the invention. The comments made above regarding dopant activation versus semiconducting material crystallization apply as well to the following discussion, and to the entire disclosure herein.

As illustrated in FIG. 14, substance 1400 comprises a target material 1410 that has been deposited in amorphous form over a substrate 1420 and an electrically insulating layer 1430. In a non-illustrated embodiment, insulating material 1430 may be omitted from substance 1400, and the strips of target material and electrically conducting material described here may be provided directly on top of substrate 1420. In that non-illustrated embodiment, wafer 1435 comprises substrate 1420 and target material 1410, plus other components as described below, but does not comprise insulating material 1430. Target material 1410, substrate 1420, and electrically insulating material 1430, along with certain further components to be named below, form a wafer 1435. As an example, target material 1410, substrate 1420, electrically insulating material 1430, and wafer 1435 can be similar to, respectively, target material 110, substrate 120, electrically insulating material 130, and wafer 135 described above and first shown in FIG. 1.

Substance 1400 further comprises a strip of electrically conducting material 1450 over electrically insulating material 1430 and adjacent to a first side of target material 1410, a strip of electrically conducting material 1470 adjacent to a second side of target material 1410 opposite the first side, a target material 1460, deposited in amorphous form, adjacent to electrically conducting material 1470, and a strip of electrically conducting material 1480 adjacent to target material 1460. As an example, electrically conducting materials 1450, 1470, and 1480 can be similar to electrically conducting material 950, first shown in FIG. 9. As another example, target material 1460 can be similar to target material 1410. The horizontal strip arrangement illustrated in FIG. 14 may be useful where the combined width of target material 1410 and target material 1460 is so great that crystallization or activation cannot occur throughout the entire width.

The process illustrated in part by FIG. 14 does not include or require an electron flood because electrically conducting materials 1450, 1470, and 1480, rather than the electron flood, act as an electron source for the electrons that perform the bond screening. FIG. 14 illustrates substance 1400 at a stage in the inter-atomic bond strength reduction process subsequent to a low temperature anneal similar to that first described above in connection with the process depicted in FIGS. 1-2. More specifically, target material 1410 and target material 1460 have been crystallized or activated. If desired, an electrical bias may be applied to electrically conducting material 1450 and/or electrically conducting materials 1470 and 1480 in order to achieve the advantages, discussed above, attendant to an electrical bias. As an example, such an electrical bias may be applied between a probe pad or pads (not shown) that are electrically connected to electrically conducting materials 1450, 1470, and 1480, or some subset thereof.

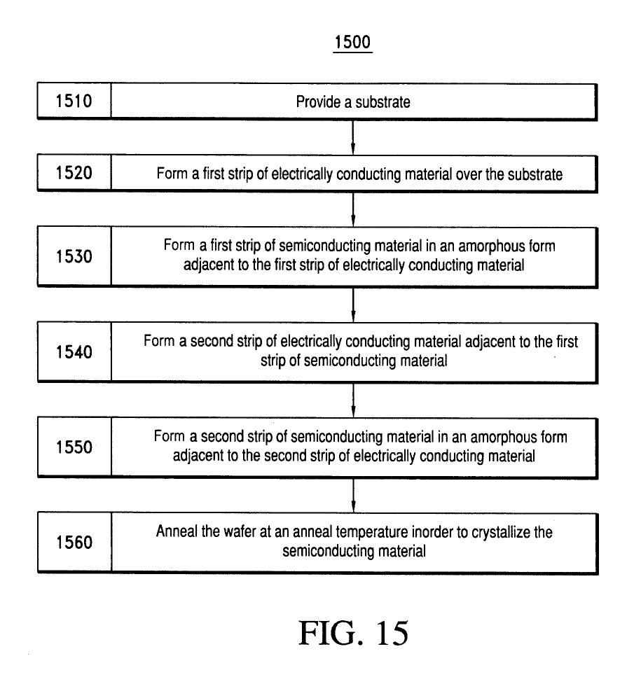

FIG. 15 is a flowchart illustrating a method 1500 of reducing an inter-atomic bond strength of a semiconducting material according to an embodiment of the invention and as shown in FIG. 14. A step 1510 of method 1500 is to provide a substrate, which for example, can be similar to substrate 1420, shown in FIG. 14.

A step 1520 of method 1500 is to deposit a first strip of electrically conducting material over the substrate, and a step 1530 of method 1500 is to deposit a first strip of semiconducting material in an amorphous form adjacent to the first strip of electrically conducting material. As an example, the electrically conducting material can be similar to electrically conducting materials 1450, 1470, or 1480, shown in FIG. 14, and the semiconducting material can be similar to target materials 1410 or 1460 which were also shown in FIG. 14.

A step 1540 of method 1500 is to deposit a second strip of electrically conducting material adjacent to the first strip of semiconducting material, and a step 1550 of method 1500 is to deposit a second strip of semiconducting material in an amorphous form adjacent to the second strip of electrically conducting material. As an example, the second strip of electrically conducting material can be similar to electrically conducting materials 1450, 1470, or 1480, shown in FIG. 14, and the second strip of semiconducting material can be similar to target materials 1410 or 1460, also shown in FIG. 14.

As an example, a structure having strips of electrically conducting material alternating with strips of semiconducting material as described above may be created by laying down a blanket layer of, in this example, the electrically conducting material, forming a mask layer on top of the blanket layer, patterning the mask layer, then transferring the pattern down into the blanket layer using an etching process. Next, a layer of semiconducting material is formed to fill in the gaps etched into the blanket layer, followed, if necessary, by an etch back or chemical-mechanical polish to planarize the composite substance. If desired, the above process may be extended to more than two materials.

A step 1560 is to anneal the wafer at an anneal temperature in order to crystallize the semiconducting material. As an example, the anneal temperature can be less than approximately 600 degrees C., and in particular can be approximately 300 degrees C. or less.

In one embodiment, method 1500 further comprises forming a diffusion barrier between at least one of the first strip of electrically conducting material and the first strip of semiconducting material, the first strip of semiconducting material and the second strip of electrically conducting material, and the second strip of electrically conducting material and the second strip of semiconducting material. As an example, the diffusion barrier can comprise a strip of titanium nitride or the like. In the same or another embodiment, the electrically conducting material can be selectively etched away following the crystallization process. Alternatively, and depending on the application, the electrically conducting material can be left in.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the method of reducing an inter-atomic bond strength discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A method of reducing an inter-atomic bond strength of a substance, the method comprising:
providing a wafer, the wafer including a target material;
after providing the wafer including the target material, annealing the wafer at an anneal temperature in order to alter a physical property of the target material; and
exposing a portion of the target material to a particle flood at an exposure temperature,
wherein:
annealing the wafer does not begin until after the wafer includes the target material; and
the exposure temperature is greater than approximately 22 degrees Celsius.

2. The method of claim 1 wherein:
the anneal temperature is less than approximately 600 degrees Celsius; and
the exposure temperature is greater than approximately 45 degrees Celsius.

3. The method of claim 2 wherein:
the anneal temperature is no greater than approximately 300 degrees Celsius; and
the exposure temperature is approximately equal to the anneal temperature.

4. The method of claim 1 wherein:
the target material comprises a collection of non-activated dopant atoms within a semiconducting material.

5. The method of claim 1 wherein:
the target material comprises a semiconducting material in an amorphous form.

6. The method of claim 5 further comprising:
forming an electrically insulating layer over the wafer before forming the semiconducting material, such that the semiconducting material is formed over the electrically insulating layer.

7. The method of claim 5 wherein:
annealing the wafer at the anneal temperature crystallizes a portion of a surface of the semiconducting material and the semiconducting material underneath the portion of the surface of the semiconducting material.

8. The method of claim 7 wherein:
the particle flood comprises a blanket electron flood; and
the portion of the surface of the semiconducting material comprises substantially all of the surface of the semiconducting material.

9. The method of claim 7 further comprising:
forming a hard mask above the semiconducting material before annealing the wafer;
patterning the hard mask;
removing selected portions of the hard mask; and
removing any remaining portions of the hard mask.

10. The method of claim 9 wherein:
the hard mask comprises a dielectric material.

11. The method of claim 9 wherein:
the hard mask comprises an electrically conducting material.

12. The method of claim 9 wherein:
the hard mask comprises a stack comprising a dielectric material and an electrically conducting material.

13. The method of claim 5 wherein:
the particle flood comprises a localized electron beam having an acceleration voltage.

14. The method of claim 13 wherein:
the localized electron beam is rastered across a surface of the semiconducting material to create an exposed pattern.

15. The method of claim 1 further comprising:
applying an electrical bias to the wafer.

16. The method of claim 1 further comprising:
providing a seed window adjacent to the target material where the target material
physically contacts the wafer,
wherein:
the seed window is capable of serving as an initiation site for crystallization.

17. A method of reducing an inter-atomic bond strength of a semiconducting material, the method comprising:
providing a wafer, the wafer including an electrically insulating layer and the semiconducting material in an amorphous form over the electrically insulating layer;
forming a diffusion barrier over the semiconducting material;
forming a layer of electrically conducting material over the diffusion barrier; and
annealing the wafer in order to crystallize the semiconducting material.

18. The method of claim 17 further comprising:
removing at least in selected areas the diffusion barrier and the layer of electrically conducting material following the annealing step in order to expose the semiconducting material for further processing of devices.

19. A method of reducing an inter-atomic bond strength of a semiconducting material, the method comprising:
providing a wafer, the wafer including an electrically insulating layer and a layer of semiconducting material in an amorphous form adjacent to the electrically insulating layer;
forming a layer of electrically conducting material adjacent to the layer of semiconducting material;
forming a second layer of semiconducting material in an amorphous form adjacent to the layer of electrically conducting material;
forming a second layer of electrically conducting material adjacent to the second layer of semiconducting material; and
annealing the wafer at an anneal temperature in order to crystallize the semiconducting material.

20. The method of claim 19 further comprising:
forming a diffusion barrier between at least one of:
the layer of semiconducting material and the layer of electrically conducting material;
the layer of electrically conducting material and the second layer of semiconducting material; and
the second layer of semiconducting material and the second layer of electrically conducting material.
